(19) United States
(12) Patent Application Publication
(10) Pub. No.: US 2017/0345831 A1
(43) Pub. Date: Nov. 30, 2017

(54) Ferroelectric Devices and Methods of Forming Ferroelectric Devices

(71) Applicant: Micron Technology, Inc., Boise, ID (US)

(72) Inventors: Ashonita A. Chavan, Boise, ID (US); Ramanathan Gandhi, Boise, ID (US); Beth R. Cook, Meridian, ID (US); Durai Vishak Nirmal Ramaswamy, Boise, ID (US)

(21) Appl. No.: 15/164,749

(22) Filed: May 25, 2016

(51) Int. Cl. H01L 27/11507; H01L 49/02

(52) U.S. Cl. CPC H01L 27/11507; H01L 28/55; H01L 28/60

(57) ABSTRACT

Some embodiments include a ferroelectric device comprising ferroelectric material adjacent an electrode. The device includes a semiconductor material-containing region along a surface of the ferroelectric material nearest the electrode. The semiconductor material-containing region has a higher concentration of semiconductor material than a remainder of the ferroelectric material. The device may be, for example, a transistor or a capacitor. The device may be incorporated into a memory array. Some embodiments include a method of forming a ferroelectric capacitor. An oxide-containing ferroelectric material is formed over a first electrode. A second electrode is formed over the oxide-containing ferroelectric material. A semiconductor material-enriched portion of the oxide-containing ferroelectric material is formed adjacent the second electrode.

### TECHNICAL FIELD

Ferroelectric devices (e.g., capacitors and transistors), and methods of forming ferroelectric devices.

### BACKGROUND

Memory is one type of integrated circuitry, and is used in computer systems for storing data. Memory may be fabricated in one or more arrays of individual memory cells. Memory cells may be written to, or read from, using digit lines (which may also be referred to as bitlines, data lines, sense lines, or data/sense lines) and access lines (which may also be referred to as wordlines). The digit lines may conductively interconnect memory cells along columns of the array, and the access lines may conductively interconnect memory cells along rows of the array. Each memory cell may be uniquely addressed through the combination of a digit line and an access line.

Memory cells may be volatile or non-volatile. Non-volatile memory cells can store data for extended periods of time including when the computer is turned off. Volatile memory dissipates and therefore requires being refreshed/rewritten, in many instances multiple times per second. Regardless, memory cells are configured to retain or store memory in at least two different selectable states. In a binary system, the states are considered as either a “0” or a “1”. In other systems, at least some individual memory cells may be configured to store more than two levels or states of information.

A capacitor is one type of electronic component that may be used in a memory cell. A capacitor has two electrical conductors separated by electrically insulating material. Energy as an electric field may be electrostatically stored within such material. One type of capacitor is a ferroelectric capacitor which has ferroelectric material as at least part of the insulating material. Ferroelectric materials are characterized by having two stable polarized states and thereby can comprise programmable material of a memory cell. The polarization state of the ferroelectric material can be changed by application of suitable programming voltages, and remains after removal of the programming voltage (at least for a time). Each polarization state has a different charge-stored capacitance from the other, and which ideally can be used to write (i.e., store) and read a memory state without reversing the polarization state until such is desired to be reversed. Less desirable, in some memory having ferroelectric capacitors the act of reading the memory state can reverse the polarization. Accordingly, upon determining the polarization state, a re-write of the memory cell is conducted to put the memory cell into the pre-read state immediately after its determination. Regardless, a memory cell incorporating a ferroelectric capacitor ideally is non-volatile due to the bi-stable characteristics of the ferroelectric material that forms a part of the capacitor. One type of memory cell has a select device electrically coupled in series with a ferroelectric capacitor.

A field effect transistor is another type of electronic component that may be used in a memory cell. These transistors comprise a pair of conductive source/drain regions having a semiconductive channel region there-between. A conductive gate is adjacent the channel region and separated there-from by a thin gate insulator material. Application of a suitable voltage to the gate allows current to flow from one of the source/drain regions to the other through the channel region. When the voltage is removed from the gate, current is largely prevented from flowing through the channel region. Field effect transistors may also include additional structure, for example reversibly programmable charge storage regions as part of the gate construction. Transistors other than field effect transistors, for example bipolar transistors, may additionally or alternately be used in memory cells.

One type of transistor is a ferroelectric field effect transistor (FeFET) wherein at least some portion of the gate construction comprises ferroelectric material. Again, such materials are characterized by two stable polarized states. These different states in field effect transistors may be characterized by different threshold voltage (Vt) for the transistor or by different channel conductivity for a selected operating voltage. Polarization state of the ferroelectric material can be changed by application of suitable programming voltages, and which results in one of high channel conductance or low channel conductance. The high and low conductance, invoked by the ferroelectric polarization state, remains after removal of the programming gate voltage (at least for a time). The status of the channel conductance can be read by applying a small drain voltage which does not disturb the ferroelectric polarization.

Capacitors and transistors may be used in circuitry other than memory circuitry. Other types of ferroelectric devices may be utilized in integrated circuitry besides, or in addition to, ferroelectric capacitors and transistors.

### BRIEF DESCRIPTION OF THE DRAWINGS

FIG. 1 is a diagrammatic cross-sectional view of a portion of an example embodiment ferroelectric device.

FIG. 1A is a diagrammatic cross-sectional view of an example embodiment ferroelectric capacitor comprising the portion of FIG. 1.

FIG. 1B is a diagrammatic cross-sectional view of an example embodiment ferroelectric transistor comprising the portion of FIG. 1.

FIG. 2 shows an example embodiment ferroelectric construction at process stages of an example embodiment method of forming an example embodiment ferroelectric capacitor.

FIG. 3 shows an example embodiment ferroelectric construction at process stages of an example embodiment method of forming an example embodiment ferroelectric capacitor.

FIG. 4 shows an example embodiment ferroelectric construction at process stages of an example embodiment method of forming an example embodiment ferroelectric capacitor.

FIG. 5 shows a portion of an example embodiment memory array comprising an example embodiment ferroelectric capacitor.

FIG. 6 shows a portion of an example embodiment memory array comprising an example embodiment ferroelectric transistor.

### DETAILED DESCRIPTION OF THE ILLUSTRATED EMBODIMENTS

Some embodiments include ferroelectric devices having ferroelectric material adjacent an electrode; and comprising a semiconductor material-containing region along a surface of the ferroelectric material nearest the electrode. The ferroelectric material may be electrically insulative. The semiconductor material-containing region has a higher concentration of semiconductor material than a remainder of the ferroelectric material. The ferroelectric devices may be, for example, ferroelectric capacitors, ferroelectric transistors, etc.

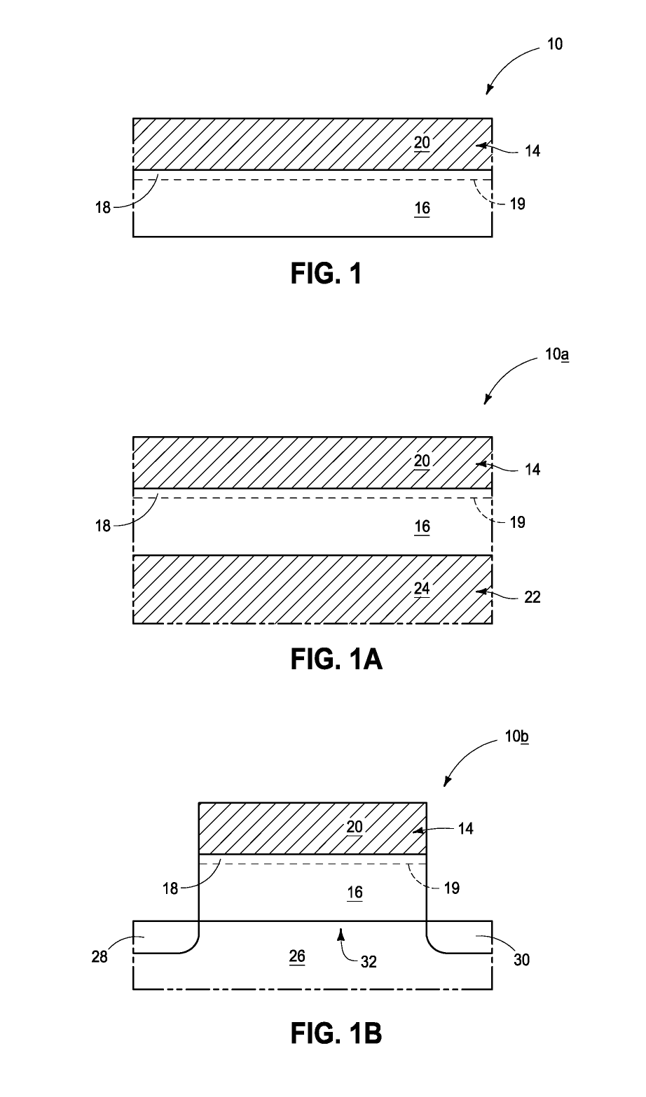

Example devices are described with reference to FIGS. 1, 1A and 1B.

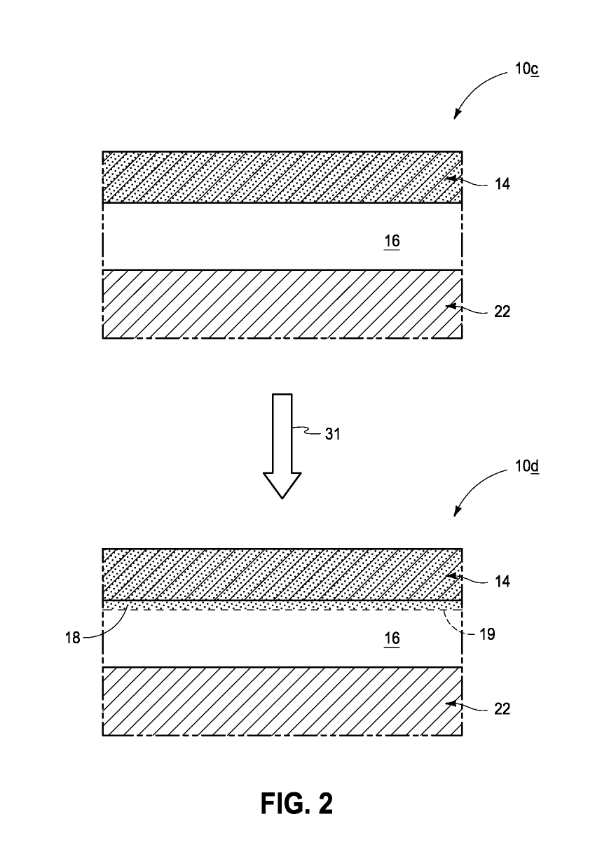

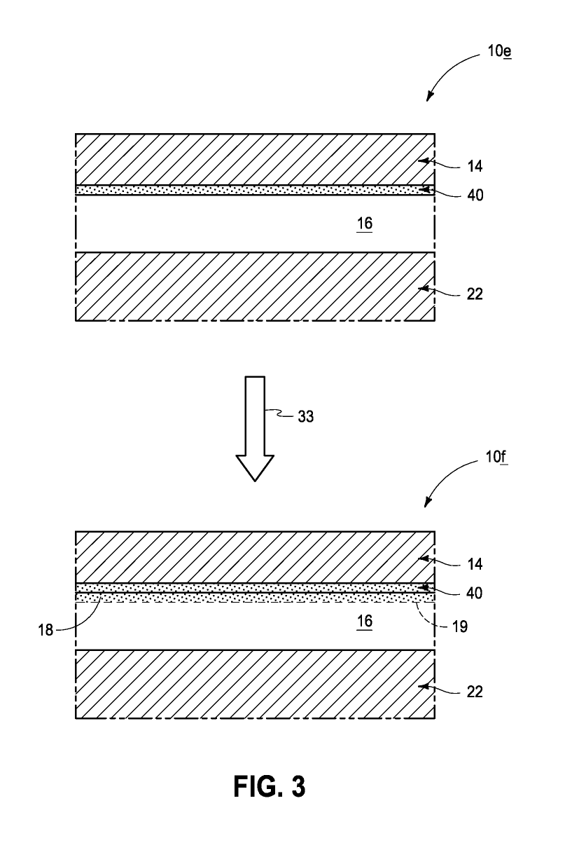

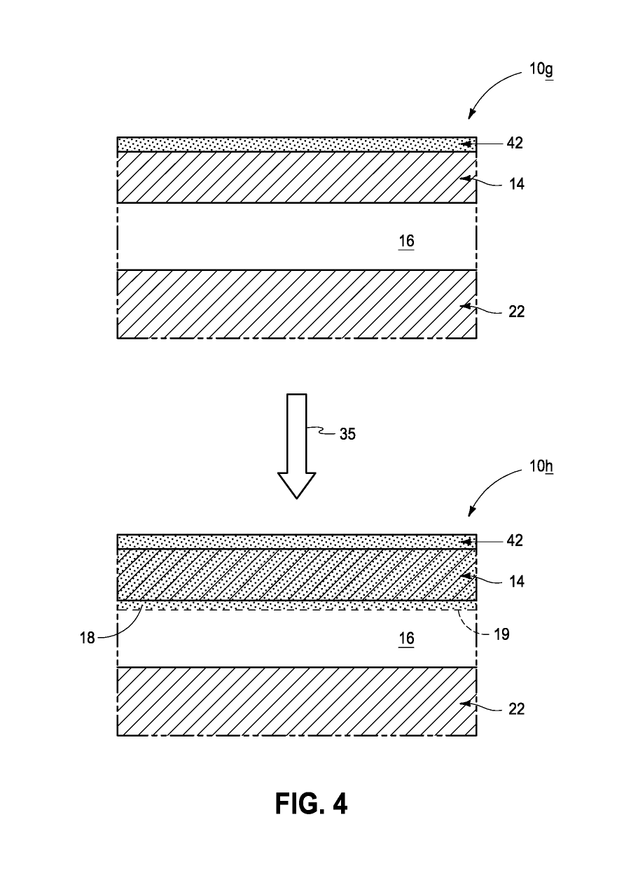

Referring to FIG. 1, a portion of a ferroelectric device 10 is illustrated. The device 10 comprises an electrode 14 over ferroelectric material 16. The ferroelectric material may comprise one or more oxides, and a problem that may occur during fabrication of the device 10 is that oxygen vacancies may be introduced along an interface between the electrode 14 and the ferroelectric material 16. Such oxygen vacancies may result from, for example, defects introduced during formation of the electrode 14 over the ferroelectric material. In some embodiments, a semiconductor-enriched region 18 is provided along an upper region of the ferroelectric material 16. The semiconductor-enriched region may comprise, for example, one or more of silicon, germanium, etc. A lower boundary of the semiconductor-enriched region is diagrammatically illustrated with a dashed-line 19. In some embodiments, the semiconductor-enriched region may be very thin; and may, be formed by diffusing semiconductor material downwardly from, or through, electrode 14 (as described in example methods of FIGS. 2 and 4), or downwardly from a semiconductor-containing layer (as described in an example method of FIG. 3). The ferroelectric material 16 may be electrically insulative.

In some embodiments, the semiconductor-enriched region 18 may be considered to be a semiconductor material-containing region along a surface of the ferroelectric material 16 nearest the electrode 14.

The semiconductor-enriched region may alleviate defects associated with oxygen vacancies in the upper region of the ferroelectric material, and may thereby improve performance of the ferroelectric device 10 relative to conventional devices lacking the semiconductor-enriched region. Such alleviation of the defects may occur by introduction of semiconductor into the vacancies and/or through other mechanisms. The improved performance of ferroelectric device 10 relative to conventional devices may be evidenced by one or more of improved remnant polarization, improved endurance, improved imprint/retention, etc.

The electrode 14 comprises electrode material 20. Such electrode material may be any suitable material; and in some embodiments may comprise, consist essentially of, or consist of one or more materials selected from the group consisting of W, WN, TiN, TiCN, TiAlN, TiAlCN, Ti—W, Ru—TiN, TiOCN, RuO, RuTiON, TaN, TaAlN, TaON and TaOCN, etc., where the formulas indicate primary constituents rather than specific stoichiometries. The electrode material may include elemental metals, alloys of two or more elemental metals, conductive metal compounds, and/or any other suitable materials. Although the electrode is illustrated to comprise a single homogeneous material, in other embodiments the electrode may comprise two or more discrete separate materials.

The ferroelectric material 16 may be any suitable material. In some embodiments the ferroelectric material 16 may comprise, consist essentially of, or consist of one or more materials selected from the group consisting of transition metal oxide, zirconium, zirconium oxide, hafnium, hafnium oxide, lead zirconium titanate, tantalum oxide, and barium strontium titanate; and having dopant therein which comprises one or more of silicon, aluminum, lanthanum, yttrium, erbium, calcium, magnesium, niobium, strontium, and a rare earth element. Although the ferroelectric material is illustrated to comprise a single homogeneous material, in other embodiments the ferroelectric material may comprise two or more discrete separate materials.

The device 10 may correspond to any of a number of ferroelectric devices. FIGS. 1A and 1B illustrate an example ferroelectric capacitor 10a and an example ferroelectric transistor 10b, respectively, comprising the various regions described above with reference to the device 10 of FIG. 1.

Referring to FIG. 1A, the ferroelectric capacitor 10a comprises the electrode 14 on one side of the ferroelectric material 16, and another electrode 22 on another side of the ferroelectric material. The electrodes 22 and 14 may be referred to as first and second electrodes, respectively.

The electrode 22 comprises electrode material 24. Such electrode material may comprise any of the compositions described above relative to the electrode material 20 of electrode 14. The electrodes 22 and 14 may comprise the same composition as one another in some embodiments, and may comprise different compositions relative to one another in other embodiments.

In the illustrated embodiment, a semiconductor-enriched region 18 is only along an interface with one of the electrodes 14 and 22, rather than there being semiconductor-enriched regions along interfaces with each of the electrodes. However, semiconductor-enriched regions could be formed along both of the electrodes 22 and 14 if desired for a particular application.

Referring to FIG. 1B, the ferroelectric transistor 10b comprises the electrode 14 as a gate above the ferroelectric material 16, and comprises semiconductor material 26 beneath the ferroelectric material. The electrode material 20 may be considered to be gate material, and in some embodiments the gate material may be a region of a wordline extending in and out of the page relative to the cross-section of FIG. 1B.

Source/drain regions 28 and 30 extend into the semiconductor material 26 on opposing sides of the ferroelectric material, and a channel region 32 extends under the ferroelectric material and between the source/drain regions. A separate gate dielectric is not shown between the ferroelectric material 16 and the channel region 32, but such could be provided if desired for particular applications.

The semiconductor material 26 may comprise any suitable material, and in some embodiments may comprise monocrystalline silicon. The source/drain regions 28 and 30 may be conductively-doped regions extending into the semiconductor material 26.

In some embodiments, material 26 may be considered a semiconductor substrate supporting the ferroelectric transistor 10b. The ferroelectric capacitor 10a of FIG. 1A could also be supported by a semiconductor substrate (not shown in FIG. 1A). The term “semiconductor substrate” means any construction comprising semiconductive material, including, but not limited to, bulk semiconductive materials such as a semiconductive wafer (either alone or in assemblies comprising other materials), and semiconductive material layers (either alone or in assemblies comprising other materials). The term “substrate” refers to any supporting structure, including, but not limited to, the semiconductor substrates described above. In some applications, a semiconductor substrate may contain one or more materials associated with integrated circuit fabrication. Such materials may include, for example, one or more of refractory metal materials, barrier materials, diffusion materials, insulator materials, etc.

Some embodiments include methods of forming ferroelectric devices. Example methods of forming ferroelectric capacitors are described with reference to FIGS. 2-4. Modifications of such methods may be utilized to form other ferroelectric devices, such as, for example, ferroelectric transistors.

Referring to FIG. 2, a capacitor construction 10c comprises ferroelectric material 16 between a pair of opposing electrodes 22 and 14. The top electrode 14 is shown to comprise semiconductor material dispersed therethrough, with such dispersed semiconductor material being diagrammatically illustrated by stippling. For instance, the electrode 14 may comprise, consist essentially of, or consist of a composition containing one or more of titanium, silicon, tungsten, hafnium, tantalum, ruthenium and nitrogen. Such composition may be represented by, for example, one or more of the chemical formulas TiSiN, WSiN, HfSiN, WSi, WSiN, TaSiN, RuSi, with the formulas indicating primary constituents of the compositions rather than indicating particular stoichiometries.

The ferroelectric material may be an oxide-containing material; and may, for example, comprise one or more of the compositions described above with reference to FIG. 1. For instance, in some embodiments the oxide-containing ferroelectric material may comprise, consist essentially of, or consist of one or both of hafnium oxide and zirconium oxide; appropriately doped to have desired ferroelectric properties. The oxide-containing ferroelectric material may be electrically insulative.

The construction 10c is converted to a construction 10d comprising the semiconductor-enriched region 18 as diagrammatically illustrated with arrow 31. Such conversion may comprise thermal treatment or other appropriate treatment to cause semiconductor material from electrode 14 to migrate into an upper portion of ferroelectric material 16 and thereby convert such upper portion to the semiconductor-enriched region 18. In embodiments in which upper electrode 14 comprises TiSiN, WSiN, HfSiN, WSi, WSiN, TaSiN or RuSi, and the semiconductor-enriched region 18 is enriched with silicon. In other embodiments, the upper electrode may comprise other semiconductor materials; such as, for example, germanium or a combination of germanium and silicon. In such other embodiments, the semiconductor-enriched region may be enriched with one or more of silicon, germanium or other suitable semiconductor material.

The conversion indicated by arrow 31 may occur with a treatment (for instance, thermal treatment) occurring after formation of electrode 14 as illustrated. Alternatively, such conversion may occur during formation of electrode 14. For instance, electrode 14 may be deposited with a mixture comprising semiconductor material, and during such deposition some of the semiconductor material may diffuse into an upper portion of ferroelectric material 16 to form the semiconductor-enriched region 18.

In some embodiments, the construction 10d of FIG. 2 may be considered to comprise an oxide-containing ferroelectric material 16 between a pair of electrodes 22 and 14, and to comprise a semiconductor material-enriched portion of the oxide-containing ferroelectric material adjacent and directly against the electrode 14. Such semiconductor material-enriched portion may comprise any suitable semiconductor material; and in some embodiments may comprise one or both of silicon and germanium. In some example embodiments the region 18 may be a silicon-enriched region of the ferroelectric material, and the electrode 14 may comprise metal and silicon. In some example embodiments the electrode 14 may comprise titanium and silicon; and in some example embodiments may comprise titanium, silicon and nitrogen. In some example embodiments the electrode 14 may comprise ruthenium and silicon; tantalum and silicon; tantalum, nitrogen and silicon; or any other combinations of silicon with the electrode materials described above with reference to FIG. 1.

Referring to FIG. 3, a capacitor construction 10e comprises ferroelectric material 16 between a pair of opposing electrodes 22 and 14, and comprises a layer 40 of semiconductor material between the top electrode 14 and the ferroelectric material 16.

The semiconductor material within layer 40 is diagrammatically illustrated by stippling. Such semiconductor material may comprise any suitable semiconductor material; and in some embodiments may comprise one or both of silicon and germanium.

The layer 40 may be very thin, and in some embodiments may have a thickness within a range of from about one monolayer to less than or equal to about 100 Å. Such layer may be formed with any suitable processing, including, for example, atomic layer deposition, chemical vapor deposition, etc. In some embodiments the construction 10e is formed by depositing ferroelectric material 16 over the electrode 22, then depositing semiconductor-containing layer 40 over the ferroelectric material 16, and finally depositing the material of electrode 14 over the layer 40.

The ferroelectric material may be an oxide-containing material; and may, for example, comprise one or more of the compositions described above with reference to FIG. 1. For instance, in some embodiments the oxide-containing ferroelectric material may comprise, consist essentially of, or consist of one or both of hafnium oxide and zirconium oxide; appropriately doped to have desired ferroelectric properties.

The construction 10e is converted to a construction 10f comprising the semiconductor-enriched region 18 as diagrammatically illustrated with arrow 33. Such conversion may comprise thermal treatment or other appropriate treatment to cause semiconductor material from layer 40 to migrate into an upper portion of ferroelectric material 16 and thereby convert such upper portion to the semiconductor-enriched region 18. In some embodiments the layer 40 may comprise one or both of silicon and germanium, and the semiconductor-enriched region 18 may therefore be enriched with one or both of silicon and germanium.

The conversion indicated by arrow 33 may occur with a treatment (for instance, thermal treatment) occurring after formation of layer 40 and electrode 14 as illustrated. Alternatively, such conversion may occur during formation of layer 40 and/or during formation of electrode 14; or may occur after formation of layer 40 and prior to formation of electrode 14.

In some embodiments, the construction 10f of FIG. 3 may be considered to comprise a semiconductor-containing layer 40 between a ferroelectric material 16 and an electrode 14, and to comprise a semiconductor material-enriched portion 18 along such layer. Such semiconductor material-enriched portion may comprise any suitable semiconductor material; and in some embodiments may comprise one or both of silicon and germanium. The layer 40 may comprise any suitable thickness, such as, for example, a thickness within a range of from about one monolayer to less than or equal to about 30 Å. In some example embodiments the region 18 may be a silicon-enriched region of the ferroelectric material, and the layer 40 may comprise, consist essentially of, or consist of silicon. In some example embodiments the electrode 14 may comprise metal, metal nitride, titanium, titanium nitride, ruthenium, tantalum, tantalum nitride, or any other of the electrode materials described above with reference to FIG. 1.

Although the construction 10f of FIG. 3 is shown comprising layer 40 over semiconductor-enriched region 18, in other embodiments an entirety of layer 40 may be consumed to form semiconductor-enriched region 18 so that none of the original layer 40 remains in construction 10f.

Referring to FIG. 4, a capacitor construction 10g comprises ferroelectric material 16 between a pair of opposing electrodes 22 and 14, and comprises a layer 42 of semiconductor material on an opposing side of the top electrode 14 from the ferroelectric material 16.

The semiconductor material within layer 42 is diagrammatically illustrated by stippling. Such semiconductor material may comprise any suitable semiconductor material; and in some embodiments may comprise one or both of silicon and germanium.

The layer 42 may be any suitable thickness, and in some embodiments may have a thickness within a range of from about 5 Å to less than or equal to about 500 Å, or less than or equal to about 30 Å. Such layer may be formed with any suitable processing, including, for example, atomic layer deposition, chemical vapor deposition, etc. In some embodiments the construction 10g is formed by depositing ferroelectric material 16 over the electrode 22, then depositing the material of electrode 14 over material 16, and finally depositing semiconductor-containing layer 42 over the electrode 14.

The ferroelectric material may be an oxide-containing material; and may, for example, comprise one or more of the compositions described above with reference to FIG. 1. For instance, in some embodiments the oxide-containing ferroelectric material may comprise, consist essentially of, or consist of one or both of hafnium oxide and zirconium oxide; appropriately doped to have desired ferroelectric properties.

The construction 10g is converted to a construction 10h comprising the semiconductor-enriched region 18 as diagrammatically illustrated with arrow 35. Such conversion may comprise thermal treatment or other appropriate treatment to cause semiconductor material from layer 42 to migrate through electrode 14 and into an upper portion of ferroelectric material 16. Such thereby converts such upper portion of material 16 to the semiconductor-enriched region 18. In some embodiments the layer 42 may comprise one or both of silicon and germanium, and the semiconductor-enriched region 18 may therefore be enriched with one or both of silicon and germanium.

The migration of semiconductor material from layer 42 through electrode 14 causes semiconductor material to be dispersed through electrode 14. In some embodiments, electrode 14 may consist of metal nitride (for instance titanium nitride) in construction 10g, and may comprise silicon, metal and nitrogen (for instance, may be TiSiN, WSiN, HfSiN, WSi, TaSiN, RuSi, etc., where the formulas indicates constituents and not specific stoichiometries) in construction 10h. The electrode 14 may be kept relatively thin to enable semiconductor material to diffuse entirely from layer 42 to ferroelectric material 16, and in some embodiments may have a thickness within a range of from about 5 Å to about 100 Å. The thickness of the electrode material may depend somewhat on the density of the electrode material, with less dense electrode materials being suitable for being thicker than denser electrode materials while still enabling desired diffusion of semiconductor material therethrough.

The conversion indicated by arrow 35 may occur with a treatment (for instance, thermal treatment) occurring after formation of layer 42 as illustrated. Alternatively, such conversion may occur during formation of layer 42.

In some embodiments, the construction 10h of FIG. 4 may be considered to comprise a semiconductor material-containing layer 42 on an opposing side of electrode 14 relative to the ferroelectric material 16, to comprise the semiconductor material of the layer 42 dispersed through electrode 14, and to comprise semiconductor material of the layer 42 within a semiconductor material-enriched portion 18 between the electrode 14 and the remainder of ferroelectric material 16. The semiconductor material of layer 42 may comprise any suitable semiconductor material; and in some embodiments may comprise one or both of silicon and germanium. In some example embodiments, the region 18 may be a silicon-enriched region of the ferroelectric material. The layer 42 may comprise any suitable thickness, such as, for example, a thickness within a range of about 5 Å to less than or equal to about 1000 Å, less than or equal to about 500 Å, or less than or equal to about 100 Å. In some example embodiments, the region 18 may be a silicon-enriched region of the ferroelectric material directly against one side of electrode 14; and the layer 42 may comprise, consist essentially of, or consist of silicon and be directly against an opposing side of electrode 14. In some example embodiments the electrode 14 of construction 10h may comprise silicon in combination with metal, metal nitride, titanium, titanium nitride, ruthenium, tantalum, tantalum nitride, or any other of the electrode materials described above with reference to FIG. 1.

In some embodiments, processing similar to that of FIG. 4 may comprise implanting or otherwise soaking semiconductor material through electrode 14, and such processing may or may not form the layer 42 on top of the electrode 14.

The methods of FIGS. 2-4 illustrate example embodiments of forming ferroelectric capacitors in which oxide-containing ferroelectric material 16 is formed over a first electrode 22, a second electrode 14 is formed over the oxide-containing ferroelectric material, and a semiconductor material-enriched portion 18 of the ferroelectric material is formed adjacent the second electrode 14. In some embodiments the semiconductor material-enriched portion 18 is may be formed prior to forming the second electrode 14 (for instance, such may occur in the embodiment of FIG. 3); and in other embodiments the semiconductor material-enriched portion 18 may be formed during or after forming the second electrode (for instance, such may occur in any of the embodiments of FIGS. 2-4).

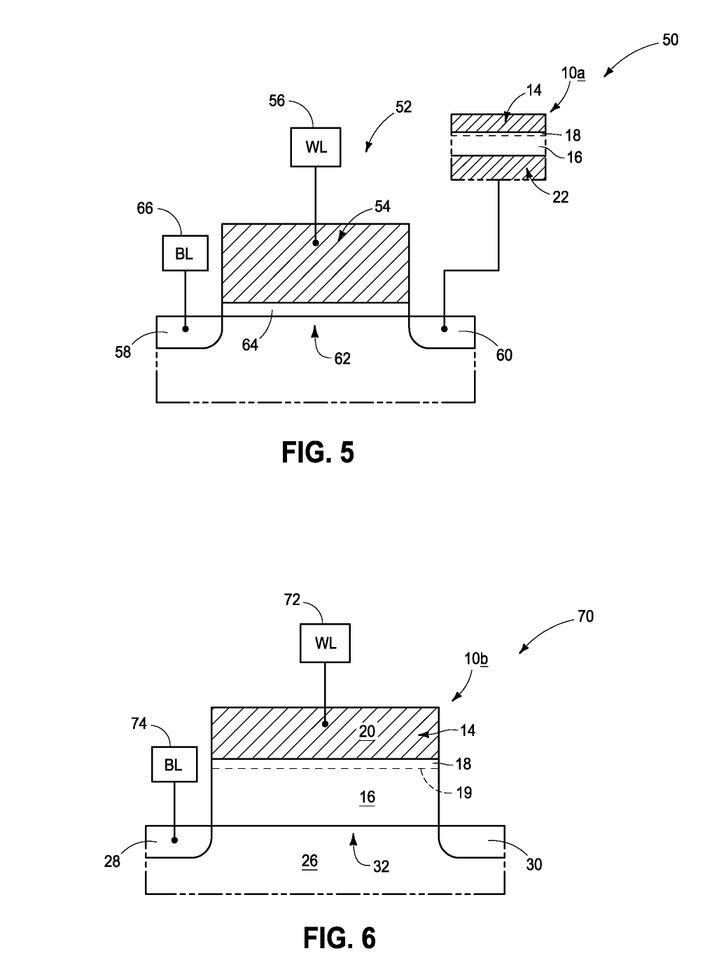

Some embodiments include memory arrays containing ferroelectric devices. Example memory arrays are described with reference to FIGS. 5 and 6.

Referring to FIG. 5, a portion of a memory array 50 is shown to comprise a ferroelectric capacitor 10a. The illustrated portion of the memory array comprises a transistor device 52 having a gate 54 connected to a wordline (WL) 56. Source/drain regions 58 and 60 are on opposing sides of the gate, and a channel region 62 extends between the source/drain regions and under the gate. The gate is spaced from the channel region by gate dielectric 64. The source/drain region 58 is electrically coupled with a bitline (BL) 66, and the source/drain region 60 is electrically coupled with the ferroelectric capacitor 10a. The ferroelectric capacitor may be a data-storage device (i.e., memory cell), and may be representative of the large number of substantially identical memory cells utilized within the memory array. The term “substantially identical” indicates that the memory cells are identical to within reasonable tolerances of fabrication and measurement.

Referring to FIG. 6, a portion of a memory array 70 is shown to comprise a ferroelectric transistor 10b. A gate of the ferroelectric transistor is electrically coupled with a wordline (WL) 72, and the source/drain region 28 is electrically coupled with a bitline (BL) 74. The transistor may be a data storage device (memory cell), and may be representative of a large number of substantially identical memory cells utilized within the memory array.

The devices discussed above may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

Unless specified otherwise, the various materials, substances, compositions, etc. described herein may be formed with any suitable methodologies, either now known or yet to be developed, including, for example, atomic layer deposition (ALD), chemical vapor deposition (CVD), physical vapor deposition (PVD), etc.

Both of the terms “dielectric” and “electrically insulative” may be utilized to describe materials having insulative electrical properties. The terms are considered synonymous in this disclosure. The utilization of the term “dielectric” in some instances, and the term “electrically insulative” in other instances, may be to provide language variation within this disclosure to simplify antecedent basis within the claims that follow, and is not utilized to indicate any significant chemical or electrical differences.

The particular orientation of the various embodiments in the drawings is for illustrative purposes only, and the embodiments may be rotated relative to the shown orientations in some applications. The description provided herein, and the claims that follow, pertain to any structures that have the described relationships between various features, regardless of whether the structures are in the particular orientation of the drawings, or are rotated relative to such orientation.

The cross-sectional views of the accompanying illustrations only show features within the planes of the cross-sections, and do not show materials behind the planes of the cross-sections in order to simplify the drawings.

When a structure is referred to above as being “on” or “against” another structure, it can be directly on the other structure or intervening structures may also be present. In contrast, when a structure is referred to as being “directly on” or “directly against” another structure, there are no intervening structures present. When a structure is referred to as being “connected” or “coupled” to another structure, it can be directly connected or coupled to the other structure, or intervening structures may be present. In contrast, when a structure is referred to as being “directly connected” or “directly coupled” to another structure, there are no intervening structures present.

Some embodiments include a ferroelectric device comprising ferroelectric material adjacent an electrode, and comprising a semiconductor material-containing region along a surface of the ferroelectric material nearest the electrode. The semiconductor material-containing region has a higher concentration of semiconductor material than a remainder of the ferroelectric material.

Some embodiments include a ferroelectric capacitor comprising oxide-containing insulative ferroelectric material between a pair of electrodes, and comprising a semiconductor material-enriched portion of the oxide-containing ferroelectric material adjacent one of the electrodes.

Some embodiments include a ferroelectric capacitor comprising a first electrode, an insulative ferroelectric material over the first electrode, and a second electrode over and directly against the ferroelectric material. The second electrode comprises metal and silicon. A silicon-enriched region of the ferroelectric material is directly against the second electrode.

Some embodiments include a ferroelectric capacitor comprising a first electrode, a ferroelectric material over the first electrode, a silicon-containing layer over and directly against the ferroelectric material, and a second electrode over and directly against the silicon-containing layer. The second electrode comprises metal.

Some embodiments include a ferroelectric capacitor comprising a first electrode, an insulative ferroelectric material over the first electrode, and a second electrode over and directly against the ferroelectric material. The second electrode comprises metal and silicon, and has a thickness within a range of from about 5 Å to about 100 Å. A silicon-containing material is over and directly against the second electrode. A silicon-enriched region of the ferroelectric material is directly against the second electrode.

Some embodiments include a method of forming a ferroelectric capacitor. An oxide-containing ferroelectric material is over a first electrode. A second electrode is formed over the oxide-containing ferroelectric material. A semiconductor material-enriched portion of the oxide-containing ferroelectric material is formed adjacent the second electrode.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A ferroelectric device, comprising:
an electrode;
ferroelectric material adjacent to the electrode; and
a semiconductor material-containing region along a surface of the ferroelectric material nearest the electrode; the semiconductor material-containing region having a higher concentration of semiconductor material than a remainder of the ferroelectric material.

2. The ferroelectric device of claim 1 wherein the ferroelectric material is electrically insulative.

3. The ferroelectric device of claim 2 wherein the semiconductor material comprises silicon.

4. The ferroelectric device of claim 2 wherein the semiconductor material comprises germanium.

5. The ferroelectric device of claim 2 wherein the semiconductor material comprises silicon and germanium.

6. The ferroelectric device of claim 2 comprising a layer of the semiconductor material between the electrode and the ferroelectric material, and wherein the semiconductor material-containing region is along said layer.

7. The ferroelectric device of claim 2 comprising the semiconductor material dispersed throughout the electrode, and wherein the semiconductor material-containing region is directly against the electrode.

8. The ferroelectric device of claim 7 further comprising a layer of the semiconductor material on an opposing side of the electrode from the ferroelectric material.

9. The ferroelectric device of claim 2 being a capacitor, and wherein the electrode is one of a pair of electrodes on opposing sides of the ferroelectric material relative to one another.

10. A memory array comprising the capacitor of claim 8 as one of a plurality of substantially identical capacitors.

11. The ferroelectric device of claim 2 being a transistor, and wherein the electrode is a transistor gate.

12. A memory array comprising the transistor of claim 11 as one of a plurality of substantially identical transistors.

13. A ferroelectric capacitor, comprising:
oxide-containing insulative ferroelectric material between a pair of electrodes; and
a semiconductor material-enriched portion of the oxide-containing insulative ferroelectric material adjacent one of the electrodes.

14. The ferroelectric capacitor of claim 13 wherein the semiconductor material comprises silicon.

15. The ferroelectric capacitor of claim 13 wherein the semiconductor material comprises germanium.

16. The ferroelectric capacitor of claim 13 wherein the semiconductor material comprises silicon and germanium.

17. The ferroelectric capacitor of claim 13 comprising a layer of the semiconductor material between the electrode and the oxide-containing insulative ferroelectric material, and wherein the semiconductor material-enriched portion is along said layer.

18. The ferroelectric capacitor of claim 13 comprising the semiconductor material dispersed throughout said one of the electrodes, and wherein the semiconductor material-enriched portion is directly against the electrode.

19. The ferroelectric capacitor of claim 18 further comprising a layer of the semiconductor material on an opposing side of said one of the electrodes from the oxide-containing insulative ferroelectric material.

20. The ferroelectric capacitor of claim 13 wherein the oxide-containing insulative ferroelectric material comprises one or more of transition metal oxide, zirconium oxide, hafnium oxide, lead zirconium titanate, tantalum oxide, and barium strontium titanate; and has dopant therein selected from the group consisting of silicon, aluminum, lanthanum, yttrium, erbium, calcium, magnesium, niobium, strontium, a rare earth element, and mixtures thereof.

21. A ferroelectric capacitor, comprising:
a first electrode;
an insulative ferroelectric material over the first electrode;
a second electrode over and directly against the insulative ferroelectric material; the second electrode comprising metal and silicon; and
a silicon-enriched region of the insulative ferroelectric material directly against the second electrode.

22. The ferroelectric capacitor of claim 21 wherein the second electrode comprises silicon together with one or more of titanium, tantalum, hafnium, tungsten and ruthenium.

23. The ferroelectric capacitor of claim 22 wherein the second electrode also comprises nitrogen.

24. The ferroelectric capacitor of claim 21 wherein the insulative ferroelectric material comprises one or both of hafnium oxide and zirconium oxide.

25. A ferroelectric capacitor, comprising:
a first electrode;
a ferroelectric material over the first electrode, at least an upper region of the ferroelectric material containing silicon;
a silicon-containing layer over and directly against the ferroelectric material; and
a second electrode over and directly against the silicon-containing layer; the second electrode comprising metal.

26. The ferroelectric capacitor of claim 25 wherein the ferroelectric material is electrically insulative.

27. The ferroelectric capacitor of claim 26 wherein the silicon-containing layer has a thickness within a range of from at least about 1 monolayer to less than or equal to about 100 Å.

28. The ferroelectric capacitor of claim 26 wherein the second electrode comprises at least one metal nitride.

29. The ferroelectric capacitor of claim 26 wherein the second electrode comprises one or more of hafnium nitride, tungsten nitride, ruthenium nitride, titanium nitride and tantalum nitride.

30. A ferroelectric capacitor, comprising:
a first electrode;
an insulative ferroelectric material over the first electrode;
a second electrode over and directly against the insulative ferroelectric material; the second electrode comprising metal and silicon, the second electrode having a thickness within a range of from about 5 Å to about 100 Å;
a silicon-containing material over and directly against the second electrode; and
a silicon-enriched region of the insulative ferroelectric material directly against the second electrode.

31. The ferroelectric capacitor of claim 30 wherein the second electrode comprises at least one metal nitride.

32. The ferroelectric capacitor of claim 30 wherein the second electrode comprises one or both of titanium nitride and tantalum nitride.

33. The ferroelectric capacitor of claim 30 wherein the silicon-containing material consists of silicon.

34. The ferroelectric capacitor of claim 33 wherein the silicon-containing material has a thickness within a range of from at least about 5 Å to less than or equal to about 500 Å.

35-41. (canceled)
